(19) United States
(12) Patent Application Publication
(10) Pub. No.: US 2020/0274102 A1
(43) Pub. Date: Aug. 27, 2020

(54) NANO-STRATIFIED ENCAPSULATION STRUCTURE, MANUFACTURING METHOD THEREFOR, AND FLEXIBLE ORGANIC LIGHT EMITTING DIODE DEVICE COMPRISING SAME

(71) Applicant: KOREA ADVANCED INSTITUTE OF SCIENCE AND TECHNOLOGY, Daejeon (KR)

(72) Inventors: Kyung Cheol CHOI, Daejeon (KR); Eun Gyo JEONG, Daejeon (KR)

(21) Appl. No.: 16/643,883

(22) PCT Filed: Jan. 18, 2018
(86) PCT No.: PCT/KR2018/000864

§ 371 Date: Mar. 3, 2020

(30) Foreign Application Priority Data
Sep. 4, 2017 (KR) 10-2017-0112708

(51) Int. Cl. H01L 51/52; H01L 51/56; H01L 51/00

(52) U.S. Cl. CPC H01L 51/5256; H01L 51/56; H01L 2251/5338; H01L 2251/558; H01L 51/0097

(57) ABSTRACT

Provided is a nano-stratified barrier having flexibility and permeability and applicable to flexible organic light-emitting diodes (FOLEDs). The nano-stratified barrier according to an embodiment of the present invention includes a substrate, a nano-stratified inorganic layer provided on the substrate and including a first inorganic layer and a second inorganic layer, and an organic layer provided on the nano-stratified inorganic layer, wherein the nano-stratified inorganic layer has voids at an interface between the first and second inorganic layers.

### TECHNICAL FIELD

The present invention relates to an organic light-emitting diode (OLED), and more particularly, to a flexible OLED (FOLED) including a nano-stratified barrier.

### BACKGROUND ART

Interest in new flexible display devices continues to grow, in keeping with the increasing demand. In spite of their sensitivity to moisture and oxygen, organic light-emitting diodes (OLEDs) are being widely investigated as promising devices for such applications. To address their environmental vulnerabilities, various types of encapsulation technologies have been studied and proposed as alternatives to the conventional fragile glass-lid encapsulation. Among these alternative approaches, thin-film encapsulation (TFE) methods are considered remarkably effective for flexible OLEDs (FOLEDs) because they offer flexibility while also eliminating edge permeation. Many types of TFE techniques have been utilized for OLEDs, such as the organic/inorganic multi-barrier, the graphene film based barrier, and the inorganic-based nanolaminate system. In order to fabricate mechanically robust FOLEDs, it is especially important to understand the behavior of barriers under bending stress. Bending stress can accelerate the growth of defects, where permeation predominantly occurs. Nonetheless, most studies have focused on measuring the low water vapor transmission rate (WVTR) of the encapsulation barrier, not its flexibility, which is one of the outstanding advantages of the TFE technology.

In this regard, an approach has been studied that involves adding a buffer layer to FOLEDs, which increases mechanical stability by controlling the neutral axis (NA). But while predicting NA behavior can be helpful in fabricating a mechanically robust TFE, adding a buffer layer requires extra processes demanding more time and resources.

### DETAILED DESCRIPTION OF THE INVENTION

### Technical Problem

The present invention provides a nano-stratified barrier having flexibility and permeability and applicable to flexible organic light-emitting diodes (FOLEDs).

The present invention also provides a method of fabricating the nano-stratified barrier.

The present invention also provides a FOLED including the nano-stratified barrier.

However, the present invention is not limited thereto.

### Technical Solution

According to an aspect of the present invention, there is provided a nano-stratified barrier including a substrate, a nano-stratified inorganic layer provided on the substrate and including a first inorganic layer and a second inorganic layer, and an organic layer provided on the nano-stratified inorganic layer, wherein the nano-stratified inorganic layer has voids at an interface between the first and second inorganic layers.

The voids may be created due to etching of a material of the first inorganic layer in a process of depositing the second inorganic layer.

The voids may reduce concentration of stress by reducing crack edge radii at tips of progressing cracks, and inhibit growth of the cracks.

The voids may have a length ranging from 1 nm to 10 nm.

A plurality of first inorganic layers and a plurality of second inorganic layers may be alternately deposited.

The nano-stratified inorganic layer may have a thickness ranging from 20 nm to 40 nm.

Each of the first and second inorganic layers may have a thickness ranging from 2 nm to 5 nm.

The first and second inorganic layers may include different materials.

The first and second inorganic layers may include at least one of aluminum oxide (Al₂O₃), aluminum nitride (AlN), silicon oxide (SiO₂), silicon nitride (SiNₓ), silicon oxynitride (SiONₓ), magnesium oxide (MgO), magnesium nitride (MgNₓ), magnesium fluoride (MgF₂), titanium oxide (TiO₂), titanium nitride (TiNₓ), hafnium oxide (HfO₂), hafnium nitride (HfNₓ), zirconium oxide (ZrO₂), zirconium nitride (ZrNₓ), zirconium sulfide (ZrS), zinc oxide (ZnO), zinc sulfide (ZnS), zinc nitride (ZnNₓ), tungsten oxide (WO₃), and yttrium oxide (Y₂O₃).

The first and second inorganic layers may be deposited by using at least one of atomic layer deposition (ALD), chemical vapor deposition (CVD), physical vapor deposition (PVD), sputtering, electron beam (e-beam) evaporation, and vacuum plating.

The nano-stratified inorganic layer may have an amorphous phase.

A plurality of organic layers and a plurality of nano-stratified inorganic layers may be alternately deposited.

The organic layer may have a thickness ranging from 50 nm to 150 nm.

The substrate may include a transparent material that transmits light, and a flexible material.

According to an aspect of the present invention, there is provided a nano-stratified barrier including a substrate, a nano-stratified inorganic layer provided on the substrate and including a zinc oxide (ZnO) layer and an aluminum oxide (Al₂O₃) layer, and an organic layer provided on the nano-stratified inorganic layer, wherein the nano-stratified inorganic layer has voids at an interface between the ZnO and Al₂O₃ layers.

The voids may be created due to etching of zinc (Zn) from the ZnO layer by an aluminum (Al) precursor used to deposit the Al₂O₃ layer, in a process of depositing the Al₂O₃ layer.

The Al precursor may include trimethylaluminum (TMA).

The ZnO layer may be deposited by using a Zn precursor including diethylzinc.

According to an aspect of the present invention, there is provided a flexible organic light-emitting diode (FOLED) including a device layer, and a nano-stratified barrier provided on the device layer, wherein the nano-stratified barrier includes a substrate, a nano-stratified inorganic layer provided on the substrate and including a first inorganic layer and a second inorganic layer, and an organic layer provided on the nano-stratified inorganic layer, and wherein the nano-stratified inorganic layer has voids at an interface between the first and second inorganic layers.

The device layer may include at least one of an electroluminescent (EL) device, a quantum dot (QD) device, and a perovskite device.

According to an aspect of the present invention, there is provided a method of fabricating a nano-stratified barrier, the method including depositing a zinc oxide (ZnO) layer, depositing an aluminum oxide (Al₂O₃) layer on the ZnO layer, and creating voids at an interface between the ZnO and Al₂O₃ layers in a process of depositing the Al₂O₃ layer due to etching of zinc (Zn) from the ZnO layer by an aluminum (Al) precursor used to deposit the Al₂O₃ layer.

### Advantageous Effects

The present invention was designed to analyze the enhanced mechanical characteristics of a nano-stratified structure, based on the defect suppression mechanism. The most important objective for an encapsulation technology is preventing the formation of critical cracks, which can be a diffusion path for oxygen and moisture. However, bending stress typically accelerates the growth of cracks in flexible devices. In the Griffith crack model, the growth speed of a crack depends on the radius of the crack edge. The defect suppression mechanism of the nano-stratified structure was investigated from this perspective. During the process of fabricating the nano-stratified barrier, naturally-occurring cracks were typically generated at the interfaces of aluminum oxide (Al₂O₃) and zinc oxide (ZnO) due to the zinc (Zn) etching by trimethylaluminum (TMA). The positive effect of the defect suppression mechanism was thus explained experimentally in the present invention.

Using a calcium (Ca) test, the water vapor transmission rate (WVTR) was increased to be 3 orders different for the multi-barrier (1.77×10⁻⁵ gm⁻²day⁻¹→1.35×10⁻² gm⁻²day⁻¹) and 1 order different for the nano-stratified barrier (7.87×10⁻⁶ gm⁻²day⁻¹→7.78×10⁻⁵ gm⁻²day⁻¹) with a 1 cm bending radius, which means that the nano-stratified barrier can endure bending stress while the multi-barrier cannot. Analysis of the cross section TEM images after the bending tests also provided notable evidence of the defect suppression mechanism. Visible critical crack paths emerged in the multi-barrier during the bending test, but were deterred by the nano-stratified structure in the nano-stratified barrier. It was also found that the enhanced physical properties of the nano-stratified structure, including the crystalline phase and the Young's modulus, can reduce applied stress.

The proven nano-stratified barrier was then successfully applied to flexible organic light-emitting diodes (FOLEDs) and showed high mechanical reliability. It should be noted that the electrical properties of the FOLEDs were not affected by the thin-film encapsulation (TFE) process. The comparison of cell images of the FOLEDs that were fabricated with the multi-barrier and with the nano-stratified barrier confirms the effectiveness of the defect suppression mechanism for preventing device failure. The device encapsulated with the multi-barrier under 0.63% strain had noticeable dark spots and lines on the active area. Finally, lifetime measurements were conducted to verify the reliability of the nano-stratified barrier. Unlike the glass-lid encapsulation technology, side permeation can be eliminated in the TFE technology, which offers improved lifetime strength. As a result, the device with TFE showed superior lifetime compared to the glass-lid encapsulated device, and moreover, after bending, the TFE device exhibited a longer lifetime than the glass-lid encapsulated device.

The above-described effects of the present invention are merely examples, and the scope of the present invention is not limited thereto.

### DESCRIPTION OF THE DRAWINGS

FIG. 1 is a schematic diagram of a flexible organic light-emitting diode (FOLED) according to an embodiment of the present invention.

FIG. 2 is a schematic diagram of a nano-stratified barrier of FIG. 1 according to an embodiment of the present invention.

FIG. 3 is a schematic diagram of a FOLED according to an embodiment of the present invention and illustrates an example of a device layer of FIG. 1.

FIG. 4 illustrates transmission electron microscope (TEM) images of a nano-stratified barrier according to an embodiment of the present invention.

FIG. 5 is a graph showing optical transmittance of a nano-stratified barrier according to an embodiment of the present invention, based on a wavelength.

FIG. 6 is a graph showing normalized conductance of a nano-stratified barrier according to an embodiment of the present invention, over time.

FIG. 7 is a graph showing a calcium (Ca) test of a nano-stratified barrier according to an embodiment of the present invention.

FIG. 8 is a graph showing a water vapor transmission rate (WVTR) of a nano-stratified barrier according to an embodiment of the present invention, based on strain.

FIG. 9 is a graph showing a Young's modulus of a nano-stratified barrier according to an embodiment of the present invention, based on a contact depth.

FIG. 10 is a graph showing an X-ray diffraction pattern of a nano-stratified barrier according to an embodiment of the present invention.

FIG. 11 is a graph showing stress applied to a nano-stratified barrier according to an embodiment of the present invention and a multi-barrier, based on strain.

FIG. 12 is a graph showing WVTR of a nano-stratified barrier according to an embodiment of the present invention and a multi-barrier, based on an applied stress.

FIG. 13 is a schematic diagram of a Griffith crack growth model which is illustrated to promote understanding of mechanical properties of a nano-stratified barrier according to an embodiment of the present invention.

FIG. 14 is a schematic diagram of a crack arrest model using microcracks, which is illustrated to promote understanding of mechanical properties of a nano-stratified barrier according to an embodiment of the present invention.

FIG. 15 is a schematic diagram showing creation of naturally-occurring voids in an inorganic layer of a nano-stratified barrier according to an embodiment of the present invention.

FIG. 16 is a graph showing the highest stress of a nano-stratified barrier according to an embodiment of the present invention at a crack edge, based on a crack edge radius.

FIG. 17 is a schematic diagram for describing a crack arrest mechanism of a nano-stratified barrier according to an embodiment of the present invention.

FIG. 18 illustrates TEM images of a nano-stratified barrier according to an embodiment of the present invention before and after a bending test.

FIG. 19 illustrates microscope images showing changes of a FOLED according to an embodiment of the present invention after a bending test.

FIG. 20 is a graph showing current density-voltage-luminance characteristics of a FOLED according to an embodiment of the present invention.

FIG. 21 is a graph showing current efficiency characteristics of a FOLED according to an embodiment of the present invention, based on a current density.

FIG. 22 is a graph showing normalized luminance of a FOLED according to an embodiment of the present invention, over time.

FIG. 23 is a graph showing an X-ray photoelectron analysis pattern for describing creation of voids in a nano-stratified barrier according to an embodiment of the present invention.

### MODE OF THE INVENTION

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. Like reference numerals denote like elements throughout. Various elements or regions in the drawings are schematically illustrated. Therefore, the scope of the present invention is not limited to the illustrated relative sizes or distances.

The present invention relates to an encapsulation barrier applicable to flexible organic light-emitting diodes (FOLEDs).

When exposed to an external environment, an electronic device including a material vulnerable to moisture and oxygen, e.g., an organic light-emitting diode (OLED), rapidly deteriorate. Therefore, thin-film encapsulation (TFE) technology for stable operation of the electronic device is indispensable. Existing TFE methods are focused on making a dense structure to protect the electronic device from the external environment such as moisture and oxygen. These methods may achieve a low water vapor transmission rate (WVTR) of an encapsulation barrier but may not be easily applied to flexible electronic devices due to lack of flexibility based on brittle inorganic materials. Unlike the existing technologies, the present invention proposes an encapsulation barrier capable of increasing flexibility by creating artificial microcracks and of achieving a low WVTR by employing multiple very thin inorganic films, and a method of fabricating the same. The artificially created microcracks (or voids) may reduce the speed of crack growth in the encapsulation barrier by making the tips of progressing cracks dull. In addition, since each of the multiple very thin inorganic films has an amorphous phase, a WVTR appropriate for an electronic device may be achieved. As such, a flexible encapsulation barrier appropriate for a flexible electronic device may be fabricated.

Compared to a method of increasing flexibility of an encapsulation barrier itself, a method of increasing flexibility by reducing the thickness of a total structure by using a thin substrate is widely used at present. In this case, although a total flexibility may be increased, the flexibility is restricted by the encapsulation barrier still having very brittle characteristics. Meanwhile, to increase the flexibility of the encapsulation barrier itself, a structure in which organic and metal films are added to an inorganic film serving as a barrier film, or a structure in which ultra-thin inorganic films are alternated has been proposed.

Vitex's Barix encapsulation including alternating organic and inorganic films was aimed to ensure flexibility by adopting flexible organic films. However, although a certain level of flexibility is achievable, the organic films have poor permeation property and thus need to be repeatedly deposited to ensure the permeation property. The encapsulation barrier including the metal films between the barrier films was aimed to ensure flexibility by using ductility of metal. However, the metal is opaque even in a small thickness and thus is not applicable to transparent electronic devices. Lastly, the encapsulation barrier in which ultra-thin inorganic films are alternated does not have any particular mechanism because flexibility is ensured by merely reducing the thickness thereof, and the advantages of using ultra-thin films are lost when a total thickness is increased to ensure permeation property.

The structure proposed by the present invention may be used as a basic structure for fabricating an encapsulation barrier. Therefore, the present invention may be extended to repeatedly deposit the basic structure and an organic or metal film. When the fabricated encapsulation barrier is applied to electronic devices, high flexibility and long lifetime may be expected. In addition, since most inorganic films are very transparent, the present invention may be applied not only to flexible electronic devices but also to transparent flexible electronic devices. Furthermore, the present invention may also be easily applied to other devices requiring the encapsulation barrier.

The present invention was aimed to fabricate a flexible encapsulation barrier appropriate for flexible electronic devices. Unlike existing thin-film encapsulation (TFE) technology, a defect suppress mechanism was achieved by artificially creating microcracks in the encapsulation barrier. In this case, the microcracks were created using chemical reaction between inorganic materials and it was demonstrated that the created microcracks may dramatically reduce the speed of crack growth. In addition, by depositing ultra-thin inorganic films, the inorganic films had a dense amorphous phase and thus excellent permeation property were achieved. As such, an encapsulation barrier capable of achieving flexibility by using relatively brittle inorganic materials was fabricated.

Interpreting how materials respond to bending stress, and its effects, will be key to applying TFE technology to FOLEDs. The first researcher to pay attention to the bending stress phenomenon was A. A. Griffith. Griffith's work was motivated by the puzzling observation that there was a difference in the stress needed to fracture a bulk material and the theoretical value for breaking atomic bonds. To solve this paradox, Griffith suggested a model, now known as Griffith's crack model, in which microscopic flaws in the bulk material lead to stress focusing, which lowers the fracture strength of the material. This model provides a clear explanation of the behavior of brittle materials under stress. In particular, the fracture strength of brittle materials is strongly dependent on the tip size of its cracks.

The present applicants propose an encapsulation barrier including a nano-stratified inorganic layer. The nano-stratified inorganic layer is obtained by applying a nano-stratified structure to an inorganic layer of a general multi-barrier in which inorganic and organic layers are alternately deposited. The nano-stratified structure may lower the WVTR thereof by making the diffusion path more complicated. Additionally, the nano-stratified structure may maintain the low WVTR after a bending test and provide high mechanical stability against fracture.

FIG. 1 is a schematic diagram of a FOLED 100 according to an embodiment of the present invention.

Referring to FIG. 1, the FOLED 100 includes a device layer 110, and a nano-stratified barrier 120 provided on the device layer 110 to encapsulate the device layer 110.

The device layer 110 may include an electronic device, for example, an electroluminescent (EL) device, a quantum dot (QD) device, or a perovskite device which is sensitive to an external environment. However, the above-mentioned electronic devices are merely examples and the present invention includes a case in which the device layer 110 includes various electronic devices.

The nano-stratified barrier 120 may be provided on the device layer 110 to encapsulate and protect the device layer 110 from the external environment.

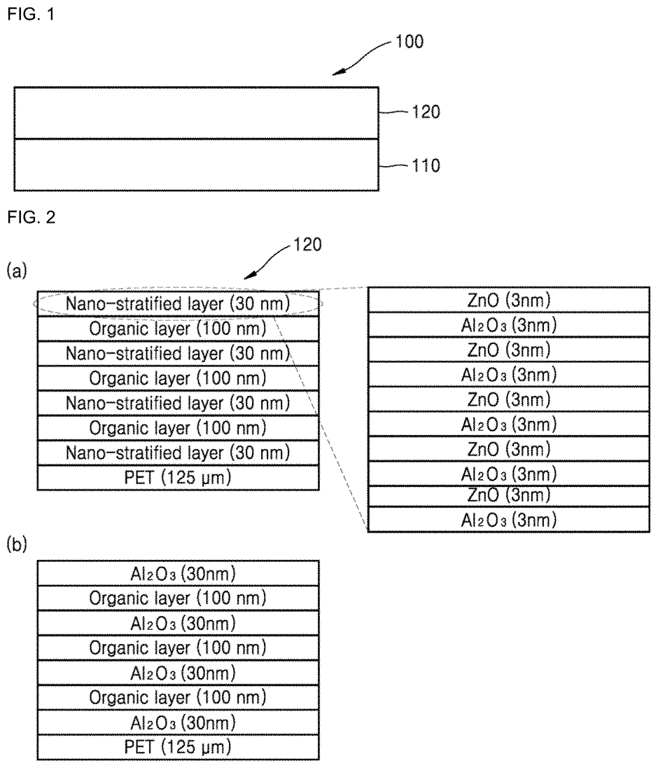

FIG. 2 is a schematic diagram of the nano-stratified barrier 120 of FIG. 1 according to an embodiment of the present invention. In FIG. 2, (a) illustrates the nano-stratified barrier 120 according to an embodiment of the present invention, and (b) illustrates a multi-barrier according to a comparative example.

Referring to FIG. 2, the nano-stratified barrier 120 according to an embodiment of the present invention includes a substrate, a nano-stratified inorganic layer provided on the substrate, and an organic layer provided on the nano-stratified inorganic layer. The nano-stratified inorganic layer may include a first inorganic layer and a second inorganic layer. A plurality of first inorganic layers and a plurality of second inorganic layers may be alternately deposited. The nano-stratified inorganic layer may have voids at an interface between the first and second inorganic layers. A plurality of organic layers and a plurality of nano-stratified inorganic layers may be alternately deposited. The nano-stratified inorganic layer may be in direct contact with the substrate. However, the above-description is merely an example and the present invention includes a case in which the organic layer is in direct contact with the substrate.

The substrate may include a transparent material that transmits light. In addition, the substrate may include a material that selectively transmits light of a desired wavelength. The substrate may include, for example, glass, quartz, silicon oxide (SiO₂), aluminum oxide (Al₂O₃), or polymer, and include at least one of, for example, polyimide, polyethylene naphthalate (PEN), polyethylene terephthalate (PET), polymethyl methacrylate (PMMA), and polydimethylsiloxane (PDMS). The substrate may be made of a flexible material, and thus a fabricated nano-stratified barrier may have flexible property. The substrate may have, for example, a thickness ranging from 100 μm to 150 μm and, more specifically, a thickness of 125 μm. However, the above-described material and thickness of the substrate are merely examples and the present invention is not limited thereto.

The organic layer may have, for example, a thickness ranging from 50 nm to 150 nm and, more specifically, a thickness of 100 nm. The nano-stratified inorganic layer may have, for example, a thickness ranging from 20 nm to 40 nm and, more specifically, a thickness of 30 nm. However, the above-described thicknesses of the organic layer and the nano-stratified inorganic layer are merely examples and the present invention is not limited thereto.

The present invention includes a case in which a part of the organic layer is substituted with a metal layer. The nano-stratified inorganic layer may be provided on the metal layer.

The first and second inorganic layers may include different materials. The first and second inorganic layers may include at least one of, for example, aluminum oxide (Al₂O₃), aluminum nitride (AlN), silicon oxide (SiO₂), silicon nitride (SiNₓ), silicon oxynitride (SiONₓ), magnesium oxide (MgO), magnesium nitride (MgNₓ), magnesium fluoride (MgF₂), titanium oxide (TiO₂), titanium nitride (TiNₓ), hafnium oxide (HfO₂), hafnium nitride (HfNₓ), zirconium oxide (ZrO₂), zirconium nitride (ZrNₓ), zirconium sulfide (ZrS), zinc oxide (ZnO), zinc sulfide (ZnS), zinc nitride (ZnNₓ), tungsten oxide (WO₃), and yttrium oxide (Y₂O₃).

Each of the first and second inorganic layers may have, for example, a thickness ranging from 2 nm to 5 nm and, more specifically, a thickness of 3 nm.

FIG. 2 illustrates a case in which PET having a thickness of 125 μm is used as the substrate, the thickness of the organic layer is 100 nm, and the thickness of the nano-stratified inorganic layer is 30 nm. In addition, FIG. 2 illustrates a case in which ZnO having a thickness of 3 nm is used as the first inorganic layer, and Al₂O₃ having a thickness of 3 nm is used as the second inorganic layer.

Naturally-occurring voids are created at an interface between the first and second inorganic layers.

In the multi-barrier illustrated in (b) of FIG. 2 according to the comparative example, organic layers each having a thickness of 100 nm and inorganic layers each having a thickness of 30 nm and made of Al₂O₃ are alternately deposited on a PET substrate.

A method of fabricating a nano-stratified barrier, according to the present invention includes depositing a ZnO layer, depositing an Al₂O₃ layer on the ZnO layer, and creating voids at an interface between the ZnO and Al₂O₃ layers in a process of depositing the Al₂O₃ layer due to etching of zinc (Zn) from the ZnO layer by an aluminum (Al) precursor used to deposit the Al₂O₃ layer.

Test Method

A method of fabricating a nano-stratified barrier, according to an embodiment of the present invention will now be described.

Preparation of Organic Layer Material

An organic layer included in a nano-stratified barrier according to the present invention was prepared as described below. A silica nanoparticle-embedded sol-gel organic-inorganic hybrid nanocomposite (hereinafter referred to as an “S—H nanocomposite”) was prepared as the organic layer.

Ultraviolet (UV)-curable cycloaliphatic-epoxy hybrid materials (hybrimer), synthesized by a sol-gel reaction between [2-(3,4-epoxycyclohexyl)ethyl]trimethoxysilane (ECTS) and diphenylsilanediol (DPSD), were stirred with Nanopox E600 (Nanoresins, Germany), based on methyl-terminated silica nanoparticles dispersed in a reactive diluent of 3,4-epoxycyclohexyl methyl 3,4-epoxycyclohexane carboxylate (EMEC).

For photo-cationic polymerization, an arylsulfonium hexafluorophosphate salt was used as an initiator. By adding propylene glycol monoether acetate, viscosity can be controlled.

The effect of the silica content on the average particle diameters and dispersion morphology of the S—H nanocomposite was also reported. To be homogeneously dispersed in the oligosiloxane resin with a 19 nm average diameter, 100% silica content will be needed. The low degree of light scattering means that the S—H nanocomposite has high transmittance, and the complicated diffusion path caused by the high silica content achieves the low WVTR value.

Fabrication of Nano-Stratified Barrier

A nano-stratified barrier according to the present invention was fabricated as described below. The following fabricating method is merely an example and the present invention is not limited thereto.

Initially, a PET substrate having a thickness of about 125 μm was prepared. Organic layers and nano-stratified inorganic layers were alternately deposited on the PET substrate. Each organic layer has a thickness of about 100 nm, and each nano-stratified inorganic layer has a thickness of about 30 nm. Specifically, a nano-stratified inorganic layer was deposited on the PET substrate, an organic layer was deposited on the nano-stratified inorganic layer, another nano-stratified inorganic layer was deposited on the organic layer, and another organic layer was deposited on the nano-stratified inorganic layer. Although a total of four nano-stratified inorganic layers and a total of three organic layers are illustrated in (a) of FIG. 2, the illustration is merely an example and the present invention is not limited thereto.

Each of the nano-stratified inorganic layers is obtained by alternately depositing Al₂O₃ layers each having a thickness of about 3 nm and ZnO layers each having a thickness of about 3 nm. Although a total of five Al₂O₃ layers and a total of five ZnO layers are illustrated in FIG. 2, the illustration is merely an example and the present invention is not limited thereto. The Al₂O₃ layers were deposited by using trimethylaluminum (TMA) as an Al precursor, and the ZnO layers were deposited by using diethylzinc (DEZ) as a Zn precursor. However, the above-mentioned precursor materials are merely examples and the present invention is not limited thereto. The Al₂O₃ and ZnO layers were deposited by using a thermal atomic layer deposition (ALD) system at a temperature of about 70° C. However, the above-described deposition method is merely an example and the present invention is not limited thereto and includes a case in which the Al₂O₃ and ZnO layers were deposited by using, for example, atomic layer deposition (ALD), chemical vapor deposition (CVD), physical vapor deposition (PVD), sputtering, electron beam (e-beam) evaporation, and vacuum plating.

For the organic layer, the S—H nanocomposite was deposited by spin-coating, then UV-cured by I-line UV light (A=365 nm, optical power density=20 mW/cm²) for about 100 seconds. After curing, the sample was dried in a vacuum chamber, which was maintained at 1.2 Torr, for 30 minutes to remove the solvent residue.

On the other hand, for the comparative example illustrated in (b) of FIG. 2, a multi-barrier was fabricated by alternately depositing inorganic Al₂O₃ layers and organic layers on a PET substrate.

Fabrication of FOLED

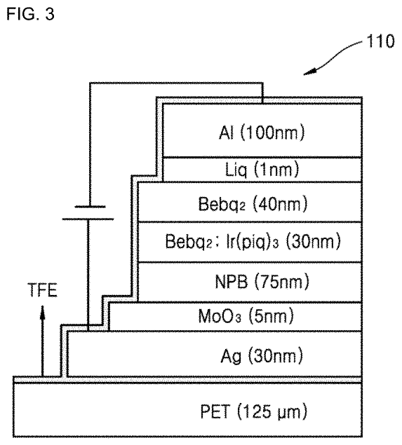

FIG. 3 is a schematic diagram of a FOLED according to an embodiment of the present invention and illustrates an example of the device layer 110 of FIG. 1.

Referring to FIG. 3, a bottom-emission type FOLED in which a PET substrate (125 μm), a silver (Ag) layer (30 nm), a molybdenum trioxide (MoO₃) layer (5 nm), a N,N′-bis(1-naphthyl)-N,N′-diphenyl-1,1′-biphenyl-4,4′-diamine (NPB) layer (75 nm), a Bebq₂:Ir(piq)₃ layer (30 nm), a Bebq₂ layer (40 nm), a 8-hydroxyquinolinolato-lithium (Liq) layer (1 nm), and an aluminum (Al) layer (100 nm) are sequentially deposited is illustrated. The layers were made by thermal evaporation, which was maintained at an average vacuum level of 1×10⁻⁶ Torr. The Ag layer serves as an anode, and is semi-transparent. The MoO₃ layer serves as a hole-injection layer, and the NPB layer serves as a hole-transport layer. An emitting layer was co-deposited with a bis(10-hydroxybenzo[h] quinolinato)beryllium complex (Bebq₂) and tris(1-phenylisoquinoline)iridium (Ir(piq)₃) as a red emission dopant. The Liq layer serves as an electron-injection layer, and the Al layer serves as a cathode.

The nano-stratified barrier according to the present invention and the multi-barrier according to the comparative example were deposited on the above-described bottom-emission type FOLED.

Characterization

For the WVTR measurement, an electrical calcium (Ca) test was conducted, which is based on the decay of the Ca metal. Initially, a 100 nm thick layer of Al was thermally deposited onto a glass substrate, which was used as an electrode. Next, the Ca pad was prepared by thermal evaporation at the 1×10⁻⁶ Torr vacuum level. The Ca pad on the glass substrate had an area of about 1.5 cm², which was the same as the permeation area, and a 250 nm height. WVTR test samples were obtained by providing the nano-stratified barrier and the multi-barrier on the Ca pad. Using a UV-curable sealant (XNR5570-Ba, Nagase Chemtex, Japan) which was sprayed from the dispenser, the WVTR test samples were sealed. During the entire process, each step was executed in a nitrogen-filled glove box connected with a thermal evaporator. The WVTR test samples were stored in a steady 30° C. and 90% relative humidity (R.H.) climate chamber. An in-situ four-point probe system (Keithley 2750, USA) was used to observe the change in resistance.

A spectrophotometer (UV-2550, Shimadzu, Japan) was used to measure optical transmittance.

A focused ion beam (Quanta 3D FEG, FEI Company, USA) was used to prepare the TEM specimen. The cross section of each encapsulation barrier was observed using a high resolution (HR)-TEM (Tecnai F30 ST, FEI Company, USA).

Indentation by a nanoindenter (Nano indenter XP, MTS, USA) was used to calculate the elastic modulus of the inorganic materials, which ranged from 50 nm to 70 nm, using a Verkovich diamond indenter with a radius of 40 nm.

A source meter (Keithley 2400, USA) and a spectrophotometer (CS-2000, Konica Minolta, Japan) were used for characterizing current density-voltage-luminance performance of the FOLEDs.

The cell images were taken by using a digital optical microscope (MicroViewer 5MP).

An OLED lifetime test system (Polaronix M6000, McScience, Korea) was used to record the lifetimes of the FOLEDs.

Properties of Nano-Stratified Barrier

In the present invention, strain c is an important variable, which is given by Equation 1.

ε=(d_{f}+dₛ)/2R, <Equation 1>
where d_{f} and dₛ are the thicknesses of the film and substrate, respectively, and R is the bending radius. In Equation 1, by keeping the total thickness (d_{f}+dₛ) of the two barriers identical, the bending radius R is the only variable for modulating the strain.

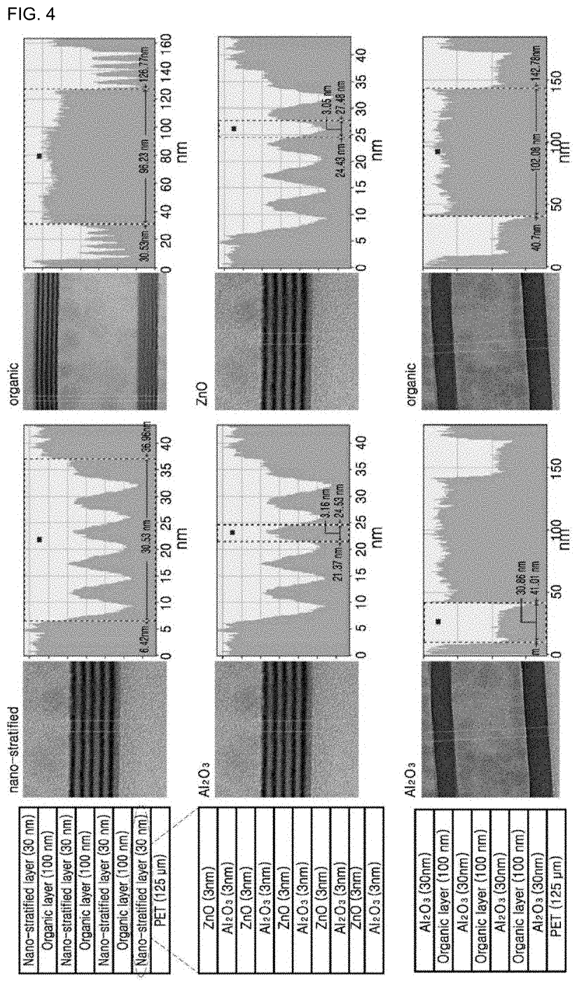

FIG. 4 illustrates transmission electron microscope (TEM) images of the nano-stratified barrier according to an embodiment of the present invention.

Referring to FIG. 4, it is shown that the nano-stratified barrier according to an embodiment of the present invention has a structure in which inorganic layers each having a thickness of 30 nm and organic layers each having a thickness of 100 nm and made of an S—H nanocomposite are alternately deposited. It is also shown that each of the inorganic layers has a structure in which Al₂O₃ layers each having a thickness of 3 nm and ZnO layers each having a thickness of 3 nm are alternately deposited.

It is also shown that the multi-barrier according to the comparative example has a structure in which inorganic layers each having a thickness of 30 nm and made of Al₂O₃ and organic layers having a thickness of 100 nm and made of an S—H nanocomposite are alternately deposited.

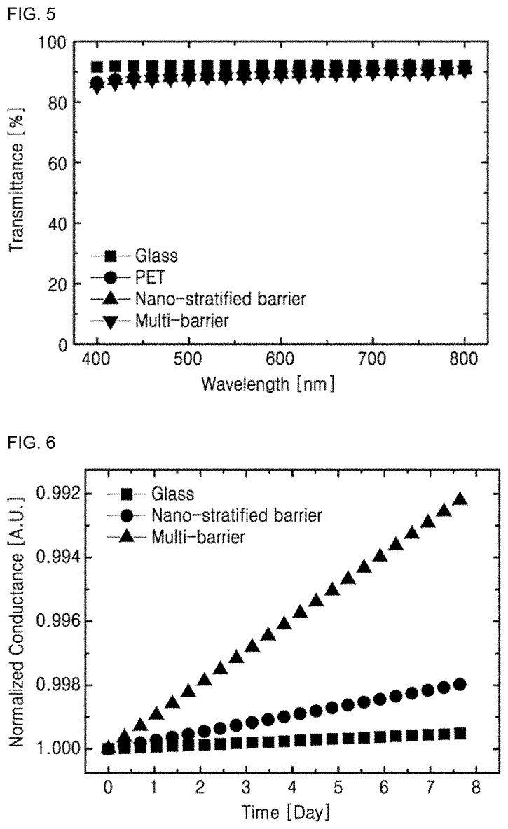

FIG. 5 is a graph showing optical transmittance of the nano-stratified barrier according to an embodiment of the present invention, based on a wavelength.

FIG. 5 shows a result of measuring optical transmittances by using air as the baseline (i.e., 100% transmittance). Both the nano-stratified barrier and the multi-barrier had a high optical transmittance greater than 80% and exhibited an optical transmittance greater than 85% in the visible region having a wavelength range from 400 nm to 800 nm.

The present inventors have observed that glass, PET, the nano-stratified barrier, and the multi-barrier all provided transparency of clearly viewing letters thereunder. This means that the nano-stratified barrier according to an embodiment of the present invention has a low optical transmittance loss and thus is applicable to transparent displays as an encapsulation. Since the optical transmittance loss is low as can be seen in FIG. 5, the nano-stratified barrier can also be applied to transparent displays.

Usually, the WVTR is used as a criterion for evaluating a barrier's encapsulation ability. The WVTR can be calculated from an electrical Ca test with Equation 2.

$$P = - n \frac{M ( {H}_{2} O )}{M ( Ca )} {δ}_{Ca} {ρ}_{Ca} \frac{l}{w} \frac{d ( 1 / R )}{dt} , \qquad 〈 Equation 2 〉$$

where P is permeation, n is the molar equivalent (2 for water), M is the molar mass, δ is the density of Ca, ρ is the resistivity of Ca, l is the length of the Ca pad, w is the width of the Ca pad, and R is the resistance of the Ca pad.

FIG. 6 is a graph showing normalized conductance of the nano-stratified barrier according to an embodiment of the present invention, over time.

Referring to FIG. 6, the nano-stratified barrier exhibited a conductance which is slightly decreased over time but is similar to that of glass. However, the multi-barrier exhibited a conductance which is remarkably decreased over time. From this result, it is conjectured that the nano-stratified barrier according to an embodiment of the present invention has a lower WVTR than the multi-barrier according to the comparative example because of its complicated diffusion path.

Since the increasing of WVTR means the deterioration of barrier characteristics, for applicability to FOLEDs, it is very effective to observe changes in the WVTR values for various strain conditions. The WVTR values were measured by applying tensile stress during a bending test of 1,000 iterations using a customized bending machine. In this case, a bending radius was changed to 1 cm, 2 cm, and 3 cm to obtain strains of 0.21%, 0.31%, and 0.63%, respectively.

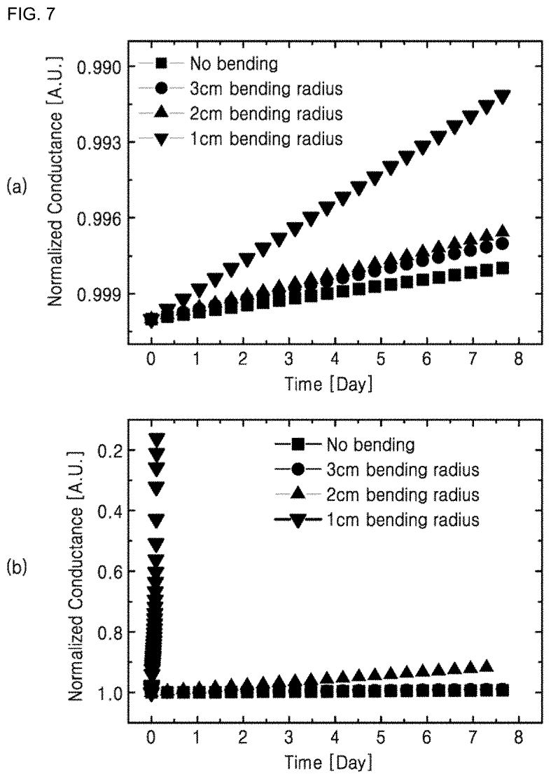

FIG. 7 is a graph showing a Ca test of the nano-stratified barrier according to an embodiment of the present invention.

Referring to FIG. 7, (a) shows normalized conductance of the nano-stratified barrier according to an embodiment of the present invention, over time based on a bending radius, and (b) shows normalized conductance of the multi-barrier according to the comparative example, over time based on a bending radius. WVTR values of the nano-stratified barrier and the multi-barrier may be calculated using the results of FIG. 7.

Table 1 shows a WVTR of the nano-stratified barrier according to an embodiment of the present invention, based on strain. In Table 1, the unit of the WVTR is “gm⁻²day⁻¹”.

TABLE 1

| | | WVTR (w/3 | WVTR (w/2 | WVTR (w/1 |
|---|---|---|---|---|
| | WVTR (0% | cm)(0.21% | cm)(0.31% | cm)(0.63% |
| Classification | strain) | strain) | strain) | strain) |
| Glass-lid | 1.82 × 10⁻⁶ | — | — | — |
| encapsulation | | | | |
| Nano-stratified | 7.87 × 10⁻⁶ | 1.56 × 10⁻⁵ | 2.51 × 10⁻⁵ | 7.78 × 10⁻⁵ |
| barrier | | | | |
| Multi-barrier | 1.77 × 10⁻⁵ | 4.51 × 10⁻⁵ | 5.16 × 10⁻⁴ | 1.35 × 10⁻² |

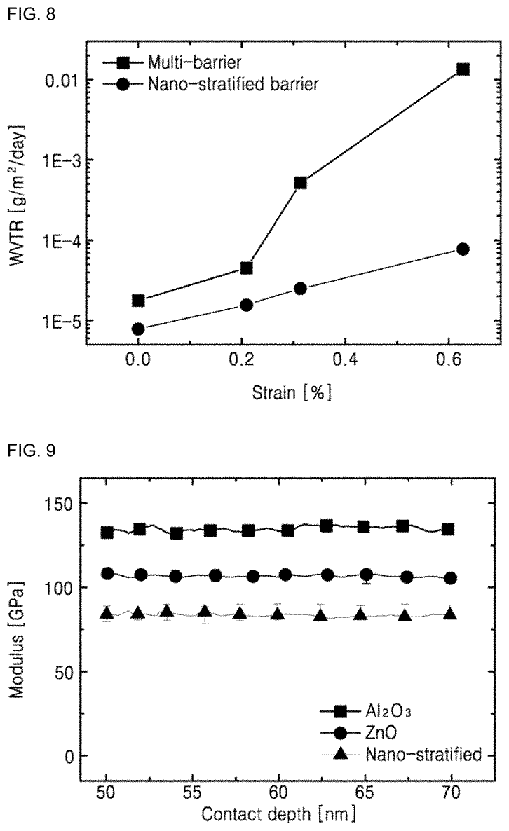

FIG. 8 is a graph showing a WVTR of the nano-stratified barrier according to an embodiment of the present invention, based on strain.

Referring to Table 1 and FIG. 8, before the bending test, the WVTR values of the glass-lid encapsulation, the nano-stratified barrier, and the multi-barrier were 1.82×10⁻⁶ gm⁻²day⁻¹, 7.87×10⁻⁶ gm⁻²day⁻¹, and 1.77×10⁻⁵ gm⁻²day⁻¹, respectively. After the bending test, the WVTR of the multi-barrier was sharply increased based on the increase in strain. However, the WVTR of the nano-stratified barrier was gradually increased based on the increase in strain, and exhibited 1.56×10⁻⁵ gm⁻²day⁻¹, 2.51×10⁻⁵ gm⁻²day⁻¹ and 7.78×10⁻⁵ gm⁻²day⁻¹ for strains of 0.21%, 0.31% and 0.63%, respectively. From this result, it is conjectured that, the nano-stratified barrier according to an embodiment of the present invention has better mechanical properties, e.g., a higher flexibility, than the multi-barrier in spite of its many inorganic layers.

Applied stress is controlled by strain, according to Hooke's law, which is expressed as Equation 3. The strain caused by the bending test is given by Equation 1.

σ=E·ε, <Equation 3>
where E is the Young's modulus and c is the strain.

Table 2 shows Young's moduli obtained using load-strain curves of Al₂O₃, ZnO, and the nano-stratified barrier in which Al₂O₃ and ZnO are alternately deposited. Values shown in Table 2 are average values for 5 iterations of the test.

TABLE 2

| | Target | | | Young's |
|---|---|---|---|---|
| | depth | Target load | Hardness | modulus |
| Material | (nm) | (mN) | (GPa) | (GPa) |
| Al₂O₃ | 700 | 45 | 8.58 | 134.36 |
| ZnO | 700 | 45 | 7.84 | 107.42 |
| Nano-stratified barrier | 700 | 45 | 5.86 | 72 |

Referring to Table 2, the nano-stratified barrier exhibited a lower hardness value and a lower Young's modulus than Al₂O₃ or ZnO.

FIG. 9 is a graph showing a Young's modulus of the nano-stratified barrier according to an embodiment of the present invention, based on a contact depth.

Referring to FIG. 9, the Young's modulus exhibited little changes even when the contact depth changed, and the nano-stratified structure exhibited a lower Young's modulus than Al₂O₃ or ZnO. This result agrees with that of Table 2.

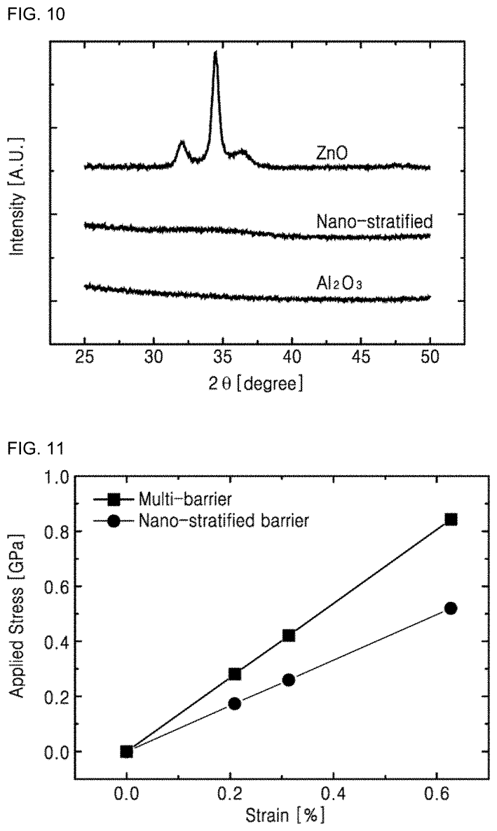

FIG. 10 is a graph showing an X-ray diffraction pattern of the nano-stratified barrier according to an embodiment of the present invention.

Referring to FIG. 10, ZnO exhibits a peak in a range from 30 degrees to 40 degrees and thus has a crystalline phase. However, Al₂O₃ and the nano-stratified inorganic layer have an amorphous phase.

This means that a lower Young's modulus of the nano-stratified structure than ZnO is because structural transition of ZnO from a polycrystalline to an amorphous morphology in the nano-stratified structure results in a decreasing tendency in the Young's modulus. This result may be supported by the Hall-Petch strengthening effect and Raghavan et al. In addition, ZnO having the amorphous phase may become denser and thus the permeation property may be further reduced.

Since the multi-barrier and the nano-stratified barrier had the same strain, according to Equation 1, the stress applied to the barriers depended on the Young's modulus, as expressed in Equation 3.

Since the multi-barrier and the nano-stratified barrier had the same strain, the stress applied to the barriers depended on the Young's modulus, as expressed in Equation 3. The applied stress may be calculated by applying the data of the Young's modulus and the strain to Equation 3.

Table 3 shows stress applied to the nano-stratified barrier according to an embodiment of the present invention and the multi-barrier, based on strain.

TABLE 3

| | Nano-stratified barrier | | | Multi-barrier | | |
|---|---|---|---|---|---|---|
| Bending radius (mm) | 30 | 20 | 10 | 30 | 20 | 10 |
| Strain (%) | 0.21 | 0.31 | 0.63 | 0.21 | 0.31 | 0.63 |
| Applied stress (GPa) | 0.17 | 0.26 | 0.52 | 0.28 | 0.42 | 0.84 |

FIG. 11 is a graph showing stress applied to a nano-stratified barrier according to an embodiment of the present invention and a multi-barrier, based on strain.

Referring to Table 3 and FIG. 11, the nano-stratified barrier suffered lower stress than the multi-barrier at the same strain. Specifically, the multi-barrier was subjected to 0.84 GPa of stress while the nano-stratified barrier was subjected to only 0.52 GPa of stress at 0.63% strain. Therefore, since a lower stress is applied at the same strain, the nano-stratified barrier may have a higher flexibility. Furthermore, Al₂O₃ has a lower value of fracture toughness, which means it has a lower critical value before fatal failure under single loading, than ZnO. Given this lower fracture toughness, Al₂O₃ was considered to be the material causing the earlier brittle fracture. In this respect, the sharp increase in the WVTR of the multi-barrier including only Al₂O₃ originated with the brittle fracture of Al₂O₃.

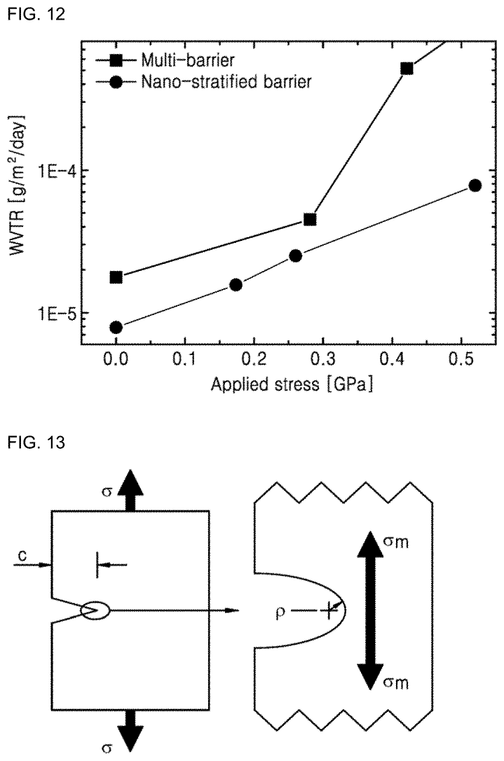

FIG. 12 is a graph showing WVTR of a nano-stratified barrier according to an embodiment of the present invention and a multi-barrier, based on an applied stress.

Referring to FIG. 12, the WVTR of the nano-stratified barrier according to an embodiment of the present invention was gradually increased until a stress of 0.52 GPa. On the other hand, the WVTR of the multi-barrier according to the comparative example was quickly increased after a stress of 0.28 GPa. These results indicate that the multi-barrier has poorer mechanical properties, e.g., a lower flexibility, than the nano-stratified barrier. This means that a significant mechanism, e.g., a defect suppression mechanism, exists which enhances the mechanical properties of the nano-stratified barrier. This defect suppression mechanism makes the nano-stratified barrier more flexible.

Analysis of Defect Suppression Mechanism of Nano-Stratified Barrier

To understand the mechanical behavior of the nano-stratified barrier according to the present invention, it is essential to consider the concentration of stress that occurs at the edge of a crack in brittle materials.

FIG. 13 is a schematic diagram of a Griffith crack growth model which is illustrated to promote understanding of mechanical properties of the nano-stratified barrier according to an embodiment of the present invention.

Referring to FIG. 13, the Griffith model assumes that numerous elliptical cracks exist in any real material, and the model is applicable to the brittle inorganic layer located within the nano-stratified barrier. Based on the Griffith crack model, the highest stress (σₘ) at the edge of a crack is expressed as Equation 4.

$${σ}_{m} ≅ 2 {σ ( \frac{c}{ρ} )}^{1 / 2} , \qquad 〈 Equation 4 〉$$

where σ is the applied stress, c is the crack length, and ρ is the radius of the crack edge.

Since the radius of a crack edge can be as tiny as interatomic spacing, the concentration of stress at the edge of a crack can be quite huge, and will induce brittle fracture. In contrast, a larger crack edge radius can reduce stress dramatically at the crack edge, as revealed by Equation 4. Importantly, this means that microcracks that have been introduced by internal stress during the inorganic fabrication process can enlarge the tip of a progressing crack, and this can blunt the stress at the crack tip.

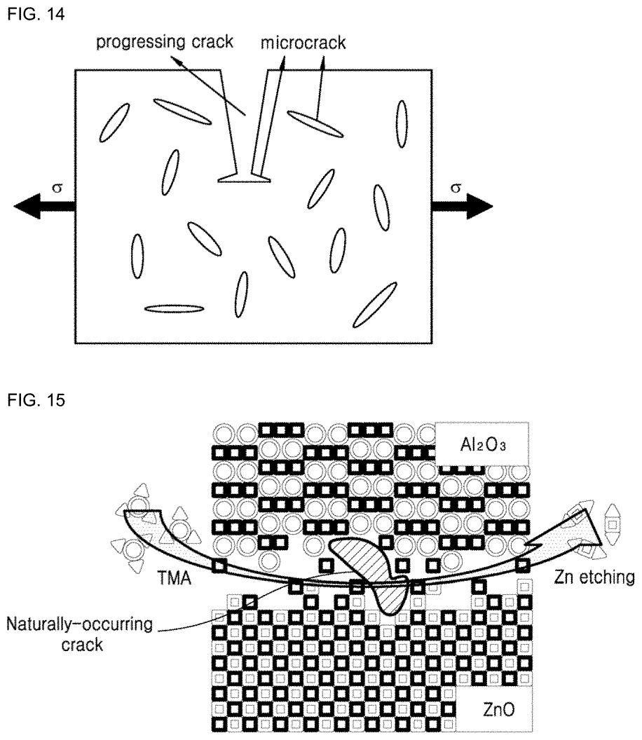

FIG. 14 is a schematic diagram of a crack arrest model using microcracks, which is illustrated to promote understanding of mechanical properties of the nano-stratified barrier according to an embodiment of the present invention.

Referring to FIG. 14, a crack edge radius at a crack tip of a progressing crack is reduced as the progressing crack meets an existing microcrack, and thus stress concentration and crack growth may be prevented to enhance the mechanical properties. Although microcracks can occur due to internal stresses, both of the encapsulation barriers were optimized to minimize internal stress, in order to minimize the permeation property. Therefore, occurrence of the microcracks may be prevented and thus the crack arrest effect may not be achieved.

FIG. 15 is a schematic diagram showing creation of naturally-occurring voids in the inorganic layer of the nano-stratified barrier according to an embodiment of the present invention.

Referring to FIG. 15, voids may naturally occur in the inorganic layer of the nano-stratified barrier according to an embodiment of the present invention in a process of depositing the ZnO and Al₂O₃ layers. Specifically, as indicted by a dashed region, voids may naturally occur at an interface between the Al₂O₃ and ZnO layers due to etching of Zn from the ZnO layer by TMA used to deposit the Al₂O₃ layer. The voids may behave like microcracks for providing the above-described crack arrest effect. The Zn etching may occur based on reaction represented by Equation 5.

ZnOH*+Al(CH₃)₃→Al(OH)(CH₃)*+Zn(CH₃)₂ <Equation 5>

Referring to Equation 5, the Zn etching by TMA creates naturally-occurring voids in the step consisting of Al₂O₃ clusters.

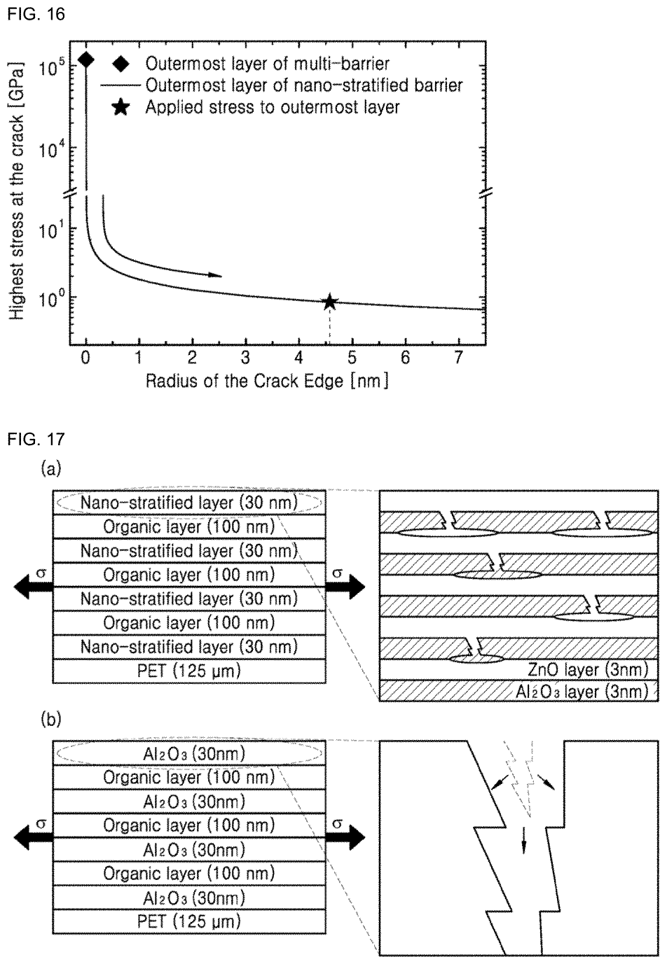

FIG. 16 is a graph showing the highest stress of the nano-stratified barrier according to an embodiment of the present invention at a crack edge, based on a crack edge radius.

Referring to FIG. 16, the multi-barrier does not have naturally-occurring voids and thus exhibits a crack edge radius equal to or close to 0 and a huge concentration of stress. However, the nano-stratified barrier has naturally-occurring voids between the Al₂O₃ and ZnO layers and thus exhibits an increase in the crack edge radius and a reduction in the highest stress as shown in the graph. The naturally-occurring voids may have, for example, a length ranging from 1 nm to 10 nm or a length ranging from 1 nm to 7 nm and, more specifically, a length of 3 nm. For example, a crack edge radius calculated based on stress applied to the outermost layer of the nano-stratified barrier may be 4.6 nm. However, the above-mentioned value is merely an example and the crack edge radius may have, for example, a value ranging from 1 nm to 10 nm or a value ranging from 1 nm to 7 nm.

The nano-stratified barrier according to the present invention may induce an inherent crack arrest mechanism, while enhancing the permeation property. The nano-stratified barrier may include naturally-occurring voids at an interface between inorganic layers, and increase an interfacial area for the voids by depositing multiple inorganic layers.

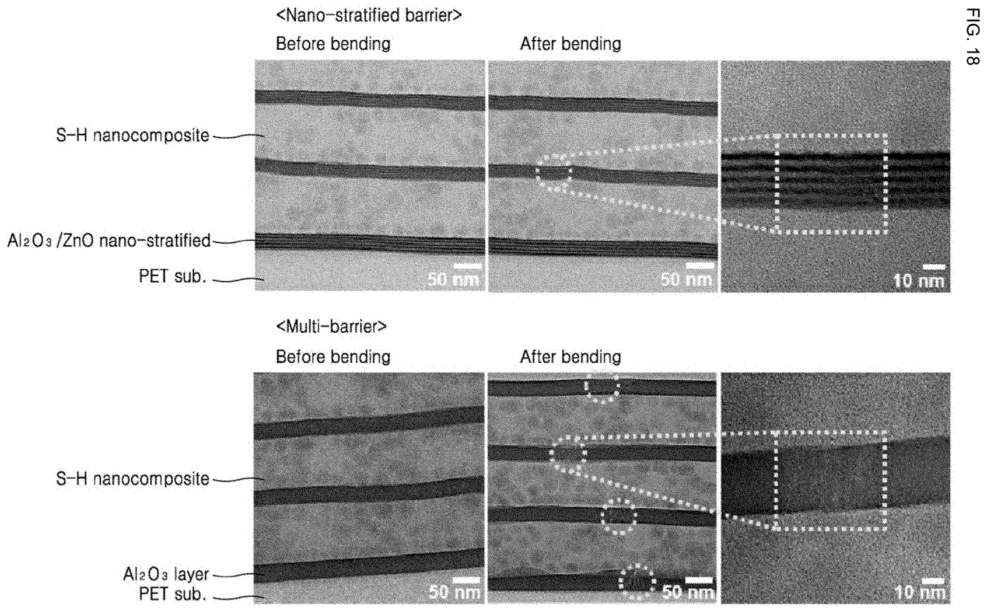

FIG. 17 is a schematic diagram for describing a crack arrest mechanism of the nano-stratified barrier according to an embodiment of the present invention.

In FIG. 17, (a) illustrates the nano-stratified barrier according to an embodiment of the present invention, and (b) illustrates the multi-barrier according to the comparative example.

Referring to FIG. 17, cracks progress in the multi-barrier while voids located at interfaces enlarge tips of cracks and thus crack growth may be prevented or suppressed in the nano-stratified barrier.

FIG. 18 illustrates TEM images of the nano-stratified barrier according to an embodiment of the present invention before and after a bending test.

Referring to FIG. 18, images of cross sections of the barriers after executing a 1 cm bending test with 1,000 iterations are illustrated. As described above, the WVTR sharply increased at 1 cm bending radius, i.e., 0.63% strain. Before the bending test, the nano-stratified inorganic layers (i.e., Al₂O₃ and ZnO) of the nano-stratified barrier and the Al₂O₃ layers of the multi-barrier were evaporated well.

However, after the bending test, fractures of the Al₂O₃ layer of the multi-barrier clearly appeared as shown in a region indicated by a dashed line. That is, critical cracks have developed in the brittle Al₂O₃ homogeneous layer, which can serve as pathways for oxygen and moisture. On the other hand, no fractures were observed after the bending test in the nano-stratified barrier as shown in a region indicated by a dashed line. That is, the nano-stratified inorganic layers of the nano-stratified barrier were not destroyed after 1,000 iterations of the bending test at 0.63% strain, which also means that the nano-stratified barrier has excellent mechanical properties.

Performance and Lifetime of FOLEDs after Bending

As described above, the defect suppression mechanism effect of the nano-stratified barrier had been verified by WVTR and TEM analysis. Performance and lifetime will now be analyzed by conducting a bending test on a FOLED with the nano-stratified barrier.

A FOLED having the structure described above in relation to FIG. 3 was fabricated with the nano-stratified barrier according to the present invention. A device encapsulated by the multi-barrier according to the comparative example was also fabricated. A 1,000-iteration bending test was conducted on both devices with various bending radii.

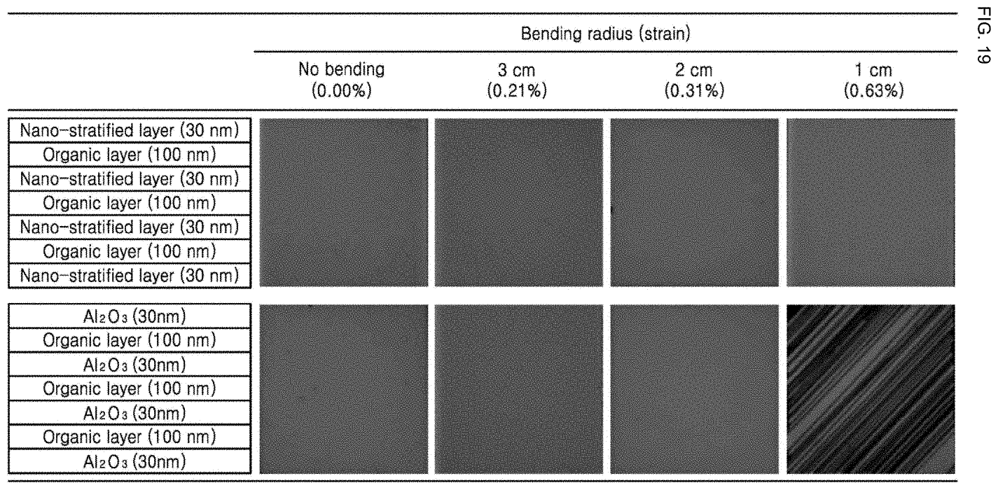

FIG. 19 illustrates microscope images showing changes in a FOLED according to an embodiment of the present invention after a bending test.

Referring to FIG. 19, the FOLED including the nano-stratified barrier was not fractured at all bending radii. However, the FOLED including the multi-barrier was fractured at 1 cm bending radius.

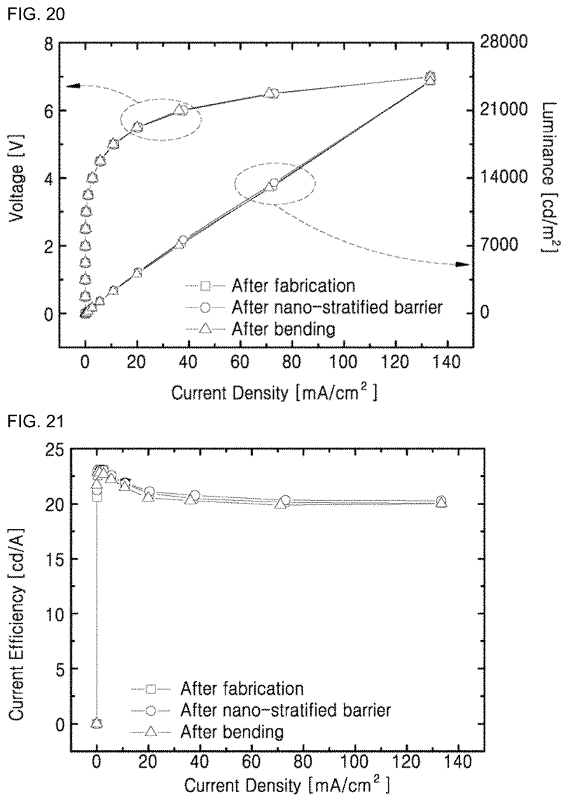

FIG. 20 is a graph showing current density-voltage-luminance characteristics of a FOLED according to an embodiment of the present invention.

Referring to FIG. 20, in the FOLED including the nano-stratified barrier according to the present invention, the electrical performance was maintained before and after a bending test of 1,000 iterations at 1 cm bending radius. The turn-on voltage was 2.5 V. At a current density of 133 mA/cm², the luminance was recorded to be 24,032 cd/m² in the initial FOLED. After TFE and the bending test, the measured luminance was 24,050 cd/m² and 24,001 cd/m², respectively.

FIG. 21 is a graph showing current efficiency characteristics of the FOLED according to an embodiment of the present invention, based on a current density.

Referring to FIG. 21, the FOLED including the nano-stratified barrier according to the present invention exhibited little changes in current efficiency after fabrication, TFE, and the bending test. The current efficiency of the FOLED was measured to be about 20 cd/A.

Referring to FIGS. 20 and 21, it appears that the TFE process and bending stress did not have a negative influence on the FOLED's electrical performance.

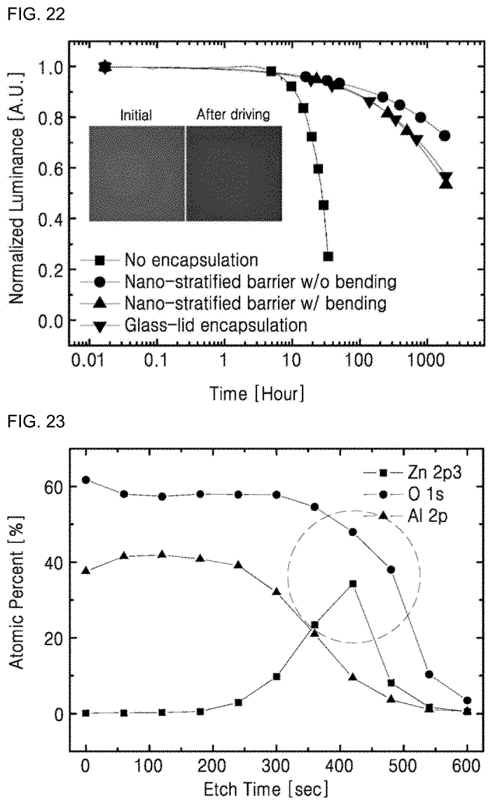

FIG. 22 is a graph showing normalized luminance of the FOLED according to an embodiment of the present invention, over time.

Referring to FIG. 22, devices with no encapsulation, with the nano-stratified barrier, with the nano-stratified barrier after 1,000 iterations of a bending test at 1 cm bending radius, and with a glass-lid encapsulation were used for comparison. All samples were continuously operated with a constant driving current of 1 mA, which produced 2,200 cd/m² of the initial luminance. The device with no encapsulation degraded rapidly and turned off after about 40 hours. Unlike the device with no encapsulation, the luminance of the passivated devices was not greatly reduced after 2,000 hours. Specifically, the luminance was reduced to 71.61% for the TFE device, and 52.37% for the device subjected to bending, 55.96% for the glass-lid only device, respectively. Even though the WVTR of the glass-lid was better than the TFE, the lifetime of the glass-lid was shorter than the TFE and comparable to the TFE after the bending test.

The inset picture in FIG. 22 represents the initial state of the passivated FOLEDs and an image of the cell after 2000 hours driving. The color of the cell was darkened but had no defects after driving.

FIG. 23 is a graph showing an X-ray photoelectron analysis pattern for describing creation of voids in the nano-stratified barrier according to an embodiment of the present invention.

Referring to FIG. 23, Al₂O₃ having a thickness of 10 nm was deposited on ZnO having a thickness of 10 nm and X-ray photoelectron analysis was performed by etching Al₂O₃ by using TMA. A Zn pattern was not measured at an early etch time because ZnO is covered by Al₂O₃, but started to appear after about 200 seconds etch time as Al₂O₃ is etched. Although ZnO should have a zinc-oxygen ratio of 50:50, the ratio was measured to be 34:48 as shown in a circular region indicated by a dashed line. This result indicates that Zn is etched by TMA. As such, it is demonstrated that the nano-stratified barrier according to the present invention may include voids created due to Zn etching.

### CONCLUSION

The present invention provided an analysis of the defect suppression mechanism, and indicated that the nano-stratified barrier, which showed excellent mechanical reliability, can be reliably applied to FOLEDs. The Griffith crack model was introduced to investigate a defect suppression mechanism. In addition to the theoretical background, a Ca test and TEM analysis were conducted to experimentally determine that the nano-stratified barrier had strong mechanical properties. A low WVTR of the nano-stratified barrier was verified by an electrical Ca test. The nano-stratified barrier still showed a low WVTR after 1,000 iterations of bending with a 1 cm radius, while a multi-barrier did not. Also, in the TEM analysis, detectable cracks were observed in the multi-barrier following a bending test, but not in the nano-stratified barrier. To determine whether the nano-stratified barrier could be applied to FOLEDs, a DC-current sweep and comparative lifetime tests were conducted. The device with a nano-stratified barrier operated equally before and after bending, and it had a similar lifetime to the glass-lid encapsulation, even following bending stress. It is concluded that the defect suppression mechanism arising from the nano-stratified structure offers resistance to bending stresses which are a major obstacle for other types of encapsulation technologies. A future direction of the present invention will be to provide more evidence in the way of fatigue analysis, and extension of the technology for application in transparent and foldable displays, since the nano-stratified barrier exhibited superior mechanical properties and high optical transmittance.

While the present invention has been particularly shown and described with reference to embodiments thereof, it will be understood by one of ordinary skill in the art that various changes in form and details may be made therein without departing from the scope of the present invention as defined by the following claims.

1. A nano-stratified barrier comprising:
a substrate;
a nano-stratified inorganic layer provided on the substrate and comprising a first inorganic layer and a second inorganic layer; and
an organic layer provided on the nano-stratified inorganic layer,
wherein the nano-stratified inorganic layer has voids at an interface between the first and second inorganic layers.

2. The nano-stratified barrier of claim 1, wherein the voids are created due to etching of a material of the first inorganic layer in a process of depositing the second inorganic layer.

3. The nano-stratified barrier of claim 1, wherein the voids reduce concentration of stress by reducing crack edge radii at tips of progressing cracks, and inhibit growth of the cracks.

4. The nano-stratified barrier of claim 1, wherein the voids have a length ranging from 1 nm to 10 nm.

5. The nano-stratified barrier of claim 1, wherein a plurality of first inorganic layers and a plurality of second inorganic layers are alternately deposited.

6. The nano-stratified barrier of claim 1, wherein the nano-stratified inorganic layer has a thickness ranging from 20 nm to 40 nm.

7. The nano-stratified barrier of claim 1, wherein each of the first and second inorganic layers has a thickness ranging from 2 nm to 5 nm.

8. The nano-stratified barrier of claim 1, wherein the first and second inorganic layers comprise different materials.

9. The nano-stratified barrier of claim 1, wherein the first and second inorganic layers comprise at least one of aluminum oxide (Al₂O₃), aluminum nitride (AlN), silicon oxide (SiO₂), silicon nitride (SiNₓ), silicon oxynitride (SiONₓ), magnesium oxide (MgO), magnesium nitride (MgNₓ), magnesium fluoride (MgF₂), titanium oxide (TiO₂), titanium nitride (TiNₓ), hafnium oxide (HfO₂), hafnium nitride (HfNₓ), zirconium oxide (ZrO₂), zirconium nitride (ZrNₓ), zirconium sulfide (ZrS), zinc oxide (ZnO), zinc sulfide (ZnS), zinc nitride (ZnNₓ), tungsten oxide (WO₃), and yttrium oxide (Y₂O₃).

10. The nano-stratified barrier of claim 1, wherein the first and second inorganic layers are deposited by using at least one of atomic layer deposition (ALD), chemical vapor deposition (CVD), physical vapor deposition (PVD), sputtering, electron beam (e-beam) evaporation, and vacuum plating.

11. The nano-stratified barrier of claim 1, wherein the nano-stratified inorganic layer has an amorphous phase.

12. The nano-stratified barrier of claim 1, wherein a plurality of organic layers and a plurality of nano-stratified inorganic layers are alternately deposited.

13. The nano-stratified barrier of claim 1, wherein the organic layer has a thickness ranging from 50 nm to 150 nm.

14. The nano-stratified barrier of claim 1, wherein the substrate comprises a transparent material that transmits light, and a flexible material.

15. A nano-stratified barrier comprising:
a substrate;
a nano-stratified inorganic layer provided on the substrate and comprising a zinc oxide (ZnO) layer and an aluminum oxide (Al₂O₃) layer; and
an organic layer provided on the nano-stratified inorganic layer,
wherein the nano-stratified inorganic layer has voids at an interface between the ZnO and Al₂O₃ layers.

16. The nano-stratified barrier of claim 15, wherein the voids are created due to etching of zinc (Zn) from the ZnO layer by an aluminum (Al) precursor used to deposit the Al₂O₃ layer, in a process of depositing the Al₂O₃ layer.

17. The nano-stratified barrier of claim 16, wherein the Al precursor comprises trimethylaluminum (TMA).

18. The nano-stratified barrier of claim 15, wherein the ZnO layer is deposited by using a Zn precursor comprising diethylzinc.

19. A flexible organic light-emitting diode (FOLED) comprising:
a device layer; and
a nano-stratified barrier provided on the device layer,
wherein the nano-stratified barrier comprises:
a substrate;
a nano-stratified inorganic layer provided on the substrate and comprising a first inorganic layer and a second inorganic layer; and
an organic layer provided on the nano-stratified inorganic layer, and
wherein the nano-stratified inorganic layer has voids at an interface between the first and second inorganic layers.

20. The FOLED of claim 19, wherein the device layer comprises at least one of an electroluminescent (EL) device, a quantum dot (QD) device, and a perovskite device.

21. A method of fabricating a nano-stratified barrier, the method comprising:
depositing a zinc oxide (ZnO) layer;
depositing an aluminum oxide (Al₂O₃) layer on the ZnO layer; and
creating voids at an interface between the ZnO and Al₂O₃ layers in a process of depositing the Al₂O₃ layer due to etching of zinc (Zn) from the ZnO layer by an aluminum (Al) precursor used to deposit the Al₂O₃ layer.
